(19) United States
(12) Patent Application Publication
(10) Pub. No.: US 2007/0221956 A1
(43) Pub. Date: Sep. 27, 2007

(54) Semiconductor device and method of fabricating the same

(75) Inventor: Satoshi Inaba, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/723,928

(22) Filed: Mar. 22, 2007

(30) Foreign Application Priority Data
Mar. 23, 2006 (JP) 2006-081559

(51) Int. Cl. H01L 31/00

(52) U.S. Cl. 257/197

(57) ABSTRACT

A semiconductor device according to one embodiment of the present invention includes: a fin including a buffer layer made of SiGe and formed on a Si layer, and a SiGe layer formed on the buffer layer, the SiGe layer having a Ge concentration corresponding to a Ge concentration of the buffer layer in an interface between the buffer layer and the SiGe layer; a gate electrode formed on a side face of the fin through a gate insulating film; a channel region formed in a region within the fin facing the gate electrode through the gate insulating film, the channel region being selectively provided within the SiGe layer of the buffer layer and the SiGe layer included in the fin; and a source region and a drain region formed within the fin, the channel region being formed between the source region and the drain region.

### CROSS-REFERENCE TO RELATED APPLICATIONS

This application is based upon and claims the benefit of priority from prior Japanese Patent Application No. 2006-081559, filed Mar. 23, 2006, the entire contents of which are incorporated herein by reference.

### BACKGROUND OF THE INVENTION

The present invention relates to a semiconductor device and a method of fabricating the same, and more particularly to a device structure of a fin-field effect transistor (FinFET) and a method of fabricating the FinFET.

In recent years, in LSIs formed on silicon substrates, the high performance promotion has been attained through scale down of elements used in the LSIs. A gate length is shortened and a gate insulating film is thinned in accordance with a so-called scaling law in a MOSFET used in a logic circuit, or a memory such as an SRAM, which results in the high performance promotion being realized in the LSIs. At present, in order to improve cutoff characteristics in a short channel region having a channel length of 30 nm or less, for example, a double-gate type fully depleted-SOI MOSFET in which an SOI substrate is used, an SOI layer is cut into slender strip-shaped portions to form a protrusion-shaped region (referred to as “fins”), and a gate electrode is made to cross the protrusion-shaped region in a two-level crossing manner, whereby a channel is adopted to be formed in each of upper surface and side faces of the protrusion-shaped substrate obtained in the cutting down process has been proposed as one kind of MIS type semiconductor device having a three-dimensional structure. This double-gate type fully depleted-SOI MOSFET, for example, is disclosed in Japanese Patent KOKAI No. 2005-19970. Also, this type of FET is especially called a FinFET.

On the other hand, recently, for the purpose of improving the device performance, especially, the current drive, new devices to obtain a high carrier mobility have been made for the channel region of the MOSFET.

For example, a strained silicon technique with which a strain is applied to silicon to modulate a sub-band structure, so that a probability of scattering of carriers, and a conductivity mass are improved, thereby obtaining a high carrier mobility is known for another conventional semiconductor device. As an example of a method of realizing this strained silicon technique, a Si layer is epitaxially grown on a layer made of a compound crystal of Si and Ge, a tensile stress is applied to the resulting Si layer by utilizing a difference (about 4.8%) in lattice constant between the compound crystal layer and the resulting Si layer, and under this condition, a high-performance n-channel FET is formed.

In addition, in the case of a p-channel FET, when a channel is formed in a layer itself containing therein Ge, a high hole mobility is obtained. Therefore, this also can contribute to the CMOS high performance promotion. In this case, a layer made of SiGe or a material near a pure Ge material may be used. In any case, however, it is necessary to form a highly concentrated Ge layer on a substrate. This necessary structure is obtained by oxidizing a SiGe region on a silicon germanium on insulator (SGOI) substrate to concentrate Ge, or by epitaxially growing a highly concentrated germanium layer on a SiGe region. This technique, for example, is disclosed in a non-patent literary document of S. Takagi et al.: IEDM Tech. Dig. pp. 57 to 61 (2003).

However, although according to the technique described in the non-patent literary document, the planar type FET can be relatively, simply formed, a problem is caused when a FinFET having a Ge-channel or SiGe-channel is supposed. For example, when a wafer having a conventional lamination structure including a SiGe layer, a SiGe layer (buffer layer), and a Si layer is subjected to a Ge concentrating process by performing oxidization to form a highly concentrated germanium layer, a substrate structure is limited to a silicon germanium on insulator (SGOI) because diffusion of Ge into a bottom portion of the substrate must be suppressed. In addition, Ge is concentrated by performing the oxidization in a vertical direction. Therefore, in this case, a thickness of a region having a high Ge concentration becomes smaller than that of the original SiGe film. Thus, since a fin height of the FinFET, that is, a maximum channel width of the FinFET depends on the thickness of the region having a high Ge concentration, the current driving force of the FinFET is necessarily limited, and the degree of freedom of a design is lost.

In addition, when a highly concentrated germanium layer is formed on the SiGe layer through the epitaxial growth, the Ge layer must be epitaxially grown after a buffer layer are formed on the Si substrate. Thus, in this case as well, a large thickness of the Ge layer cannot be obtained. Even if the Ge layer can be formed to have a large thickness, a compressive stress is weak in an upper portion of the fin although the compressive stress is enough in a region close to the base of the fin. As a result, there is encountered such a problem that the stress is not unified within the channel.

### BRIEF SUMMARY OF THE INVENTION

A semiconductor device according to one embodiment of the present invention includes:

a fin including a buffer layer made of SiGe and formed on a Si layer, and a SiGe layer formed on the buffer layer, the SiGe layer having a Ge concentration corresponding to a Ge concentration of the buffer layer in an interface between the buffer layer and the SiGe layer;

a gate electrode formed on a side face of the fin through a gate insulating film;

a channel region formed in a region within the fin facing the gate electrode through the gate insulating film, the channel region being selectively provided within the SiGe layer of the buffer layer and the SiGe layer included in the fin; and

a source region and a drain region formed within the fin, the channel region being formed between the source region and the drain region.

A semiconductor device according to another embodiment of the present invention includes:

a p-channel transistor having a first fin including a first buffer layer made of SiGe and formed on a Si layer, and a first SiGe layer formed on the first buffer layer, the first SiGe layer having a Ge concentration corresponding to a Ge concentration of the first buffer layer in an interface between the first buffer layer and the first SiGe layer, a first gate electrode formed on a side face of the first fin through a first gate insulating film, a first channel region formed in a region within the first fin facing the first gate electrode through the first gate insulating film, the first channel region being selectively provided within the first SiGe layer of the first buffer layer and the first SiGe layer included in the first fin, and a first source region and a first drain region formed within the first fin, the first channel region being formed between the first source region and the first drain region; and

an n-channel transistor having a second fin formed on the Si layer, a second gate electrode formed on a side face of the second fin through a second gate insulating film, a second channel region formed in a region within the second fin facing the second gate electrode through the second gate insulating film, the second channel region having a Ge concentration smaller than that of the first channel region, and a second source region and a second drain region formed within the second fin, the second channel region being formed between the second source region and the second drain region.

A method of fabricating a semiconductor device according to still another embodiment of the present invention includes:

patterning a substrate formed by laminating a Si layer, a buffer layer made of SiGe, and a SiGe layer having a Ge concentration corresponding to a Ge concentration of the buffer layer in an interface between the buffer layer and the SiGe layer in predetermined shape to form a fin;

oxidizing surfaces of the buffer layer and the SiGe layer of the fin to form an oxide layer in order to increase the Ge concentration of the fin;

removing the oxide layer by performing etching;

forming a gate insulating film on a side face of the fin from which the oxide layer is removed by performing the etching;

forming a gate electrode on the side face of the fin through the gate-insulating film; and

implanting ions into the fin by using the gate electrode as a mask to form a source region and a drain region.

### BRIEF DESCRIPTION OF THE DRAWINGS

FIG. 1 is a perspective view of a p-channel FinFET as a semiconductor device according to a first embodiment of the present invention;

FIGS. 2A to 2P are respectively perspective views showing processes for fabricating the p-channel FinFET according to the first embodiment of the present invention;

FIGS. 3A to 3C are respectively perspective views showing processes for fabricating a p-channel FinFET according to a second embodiment of the present invention;

FIGS. 4A to 4K are respectively cross sectional views showing processes for fabricating an n-channel FinFET and a p-channel FinFET according to a third embodiment of the present invention;

FIG. 5 is a cross sectional view showing a substrate in which different layers are epitaxially grown in a p-channel FinFET region and an n-channel FinFET region on a Si layer according to a fourth embodiment of the present invention; and

FIGS. 6A to 6P are respectively cross sectional views showing processes for fabricating a FinFET and a planar type FET according to a fifth embodiment of the present invention.

### DETAILED DESCRIPTION OF THE INVENTION

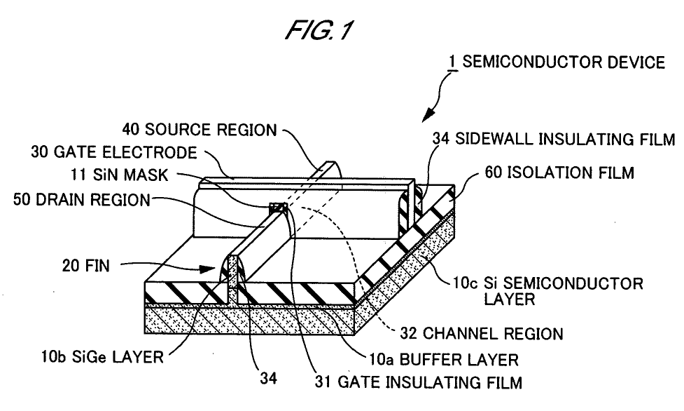

FIG. 1 is a perspective view showing a structure of a p-channel FinFET (hereinafter referred to as “a p-FinFET”) as a semiconductor device according to a first embodiment of the present invention.

A p-FinFET has a fin 20 including a source region 40 and a drain region 50 each of which is formed to have a predetermined height, and a gate electrode 30. Elements are isolated from one another through an isolation film 60.

A thickness of the fin 20, for example, is 20 nm and a height of the fin 20, for example, is in the range of 50 to 100 nm. The fin 20 has a buffer layer 10a formed on a Si layer 10c, and a SiGe layer 10b formed on the buffer layer 10a.

The buffer layer 10a is made of SiGe, and a Ge concentration of the buffer layer 10a gradually increases substantially along a height direction of the fin 20.

The SiGe layer 10b has a nearly uniform Ge concentration corresponding to the Ge concentration of the buffer layer 10a in an interface between the SiGe layer 10b and the buffer layer 10a. Preferably, the SiGe layer 10b has nearly the same Ge concentration as that of the buffer layer 10a in the interface between the SiGe layer 10b and the buffer layer 10a. In addition, the SiGe layer 10b contains therein an n-type impurity having a predetermined concentration.

In the fin 20, a channel region 32 facing a gate electrode 30 through a gate insulating film 31 is formed within a region of the SiGe layer 10b in a portion located below with respect to the gate electrode 30.

A source region 40 and a drain region 50 are respectively formed on both sides of the channel region 32 facing the gate electrode 30 within the SiGe layer 10b through the gate insulating film 31. Ions of a p-type impurity such as boron (B) are implanted with a predetermined concentration into the upper surface of the fin 20, thereby forming the source region 40 and the drain region 50. Note that, the p-FinFET includes generally constituent elements other than the above-mentioned constituent elements although their illustrations are omitted here. That is to say, contact portions, wiring portions and the like which are used to apply voltages to the source region 40 and the drain region 50, respectively, are provided in the p-FinFET in addition to the above-mentioned constituent elements. The semiconductor device 1 according to the first embodiment of the present invention will be described in detail hereinafter while a method of fabricating the same will be described in detail.

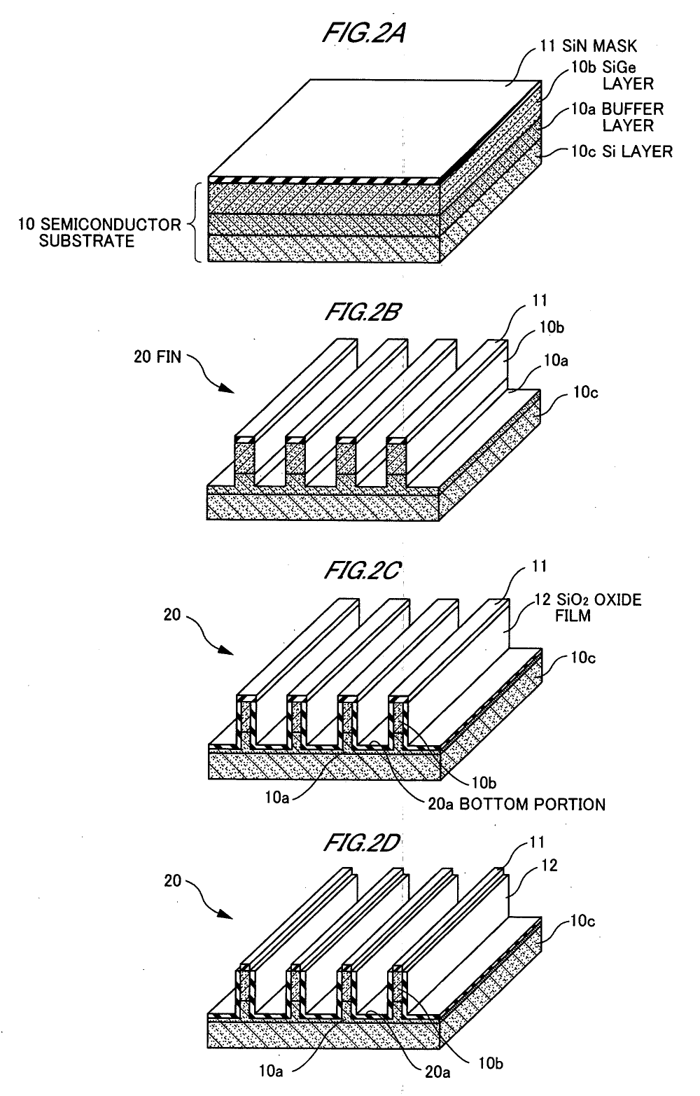

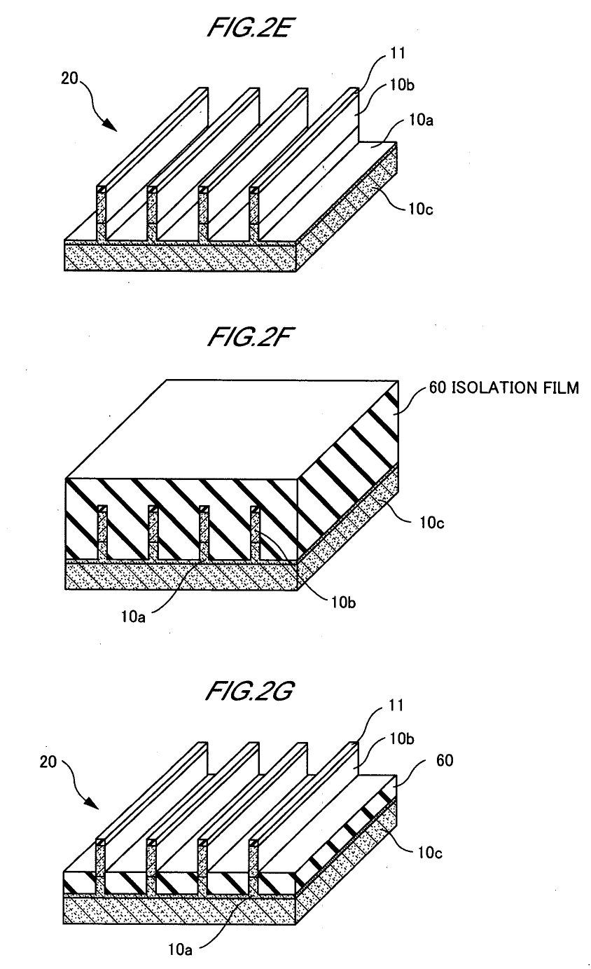

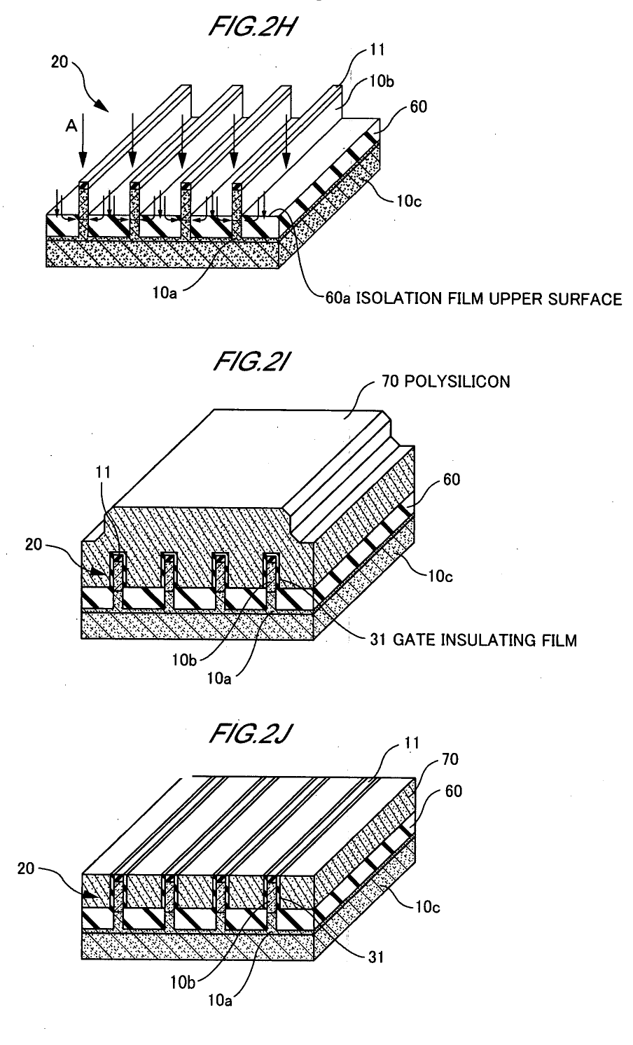

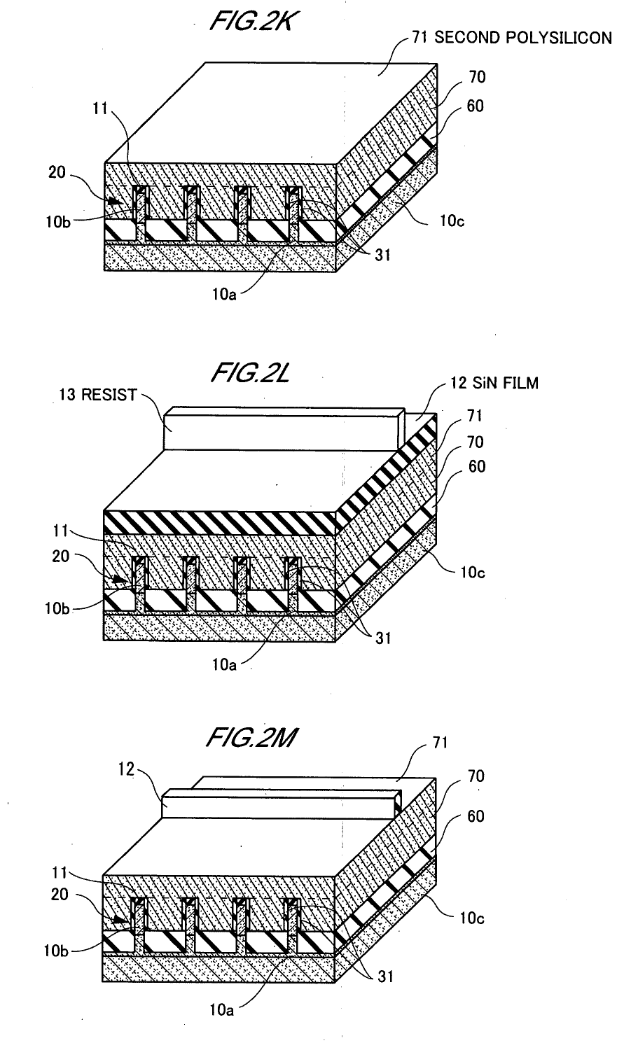

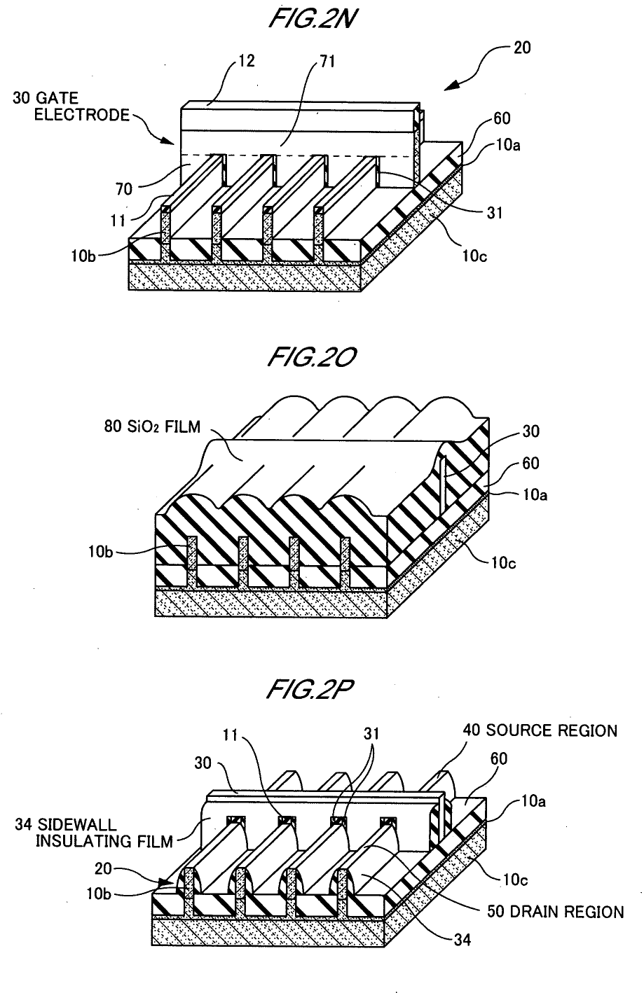

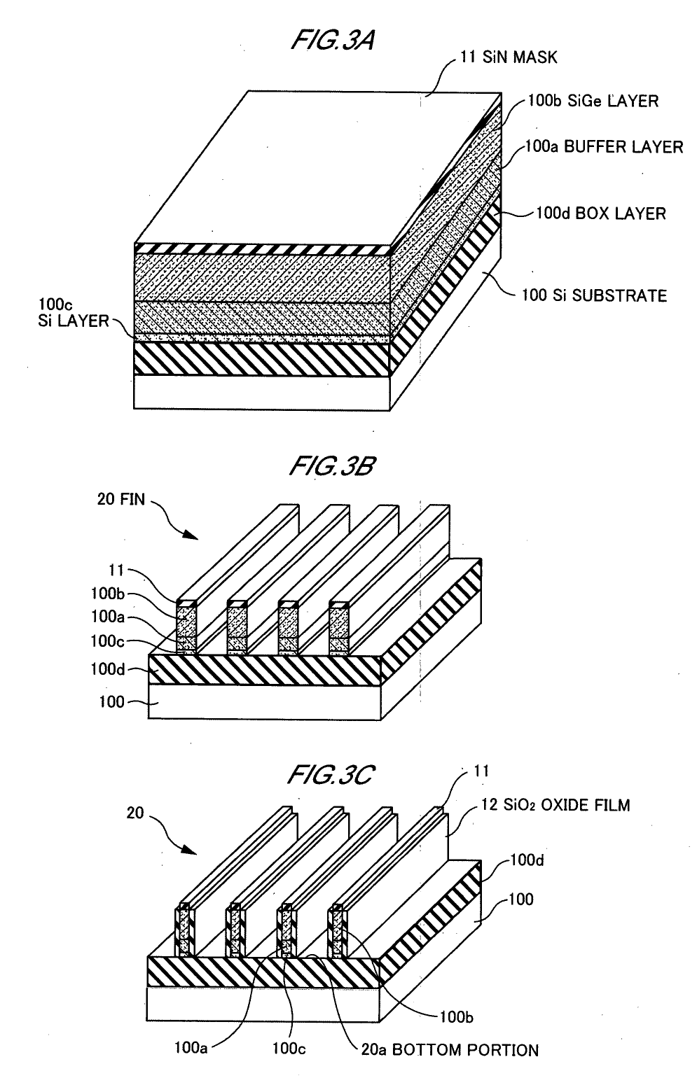

FIGS. 2A to 2P are respectively perspective views showing processes for fabricating the p-FinFET according to the first embodiment of the present invention.

(1a) The buffer layer 10a is formed on the Si layer 10c by utilizing a chemical vapor deposition (CVD) method, and the SiGe layer 10b is formed on the buffer layer 10a to have a predetermined Ge concentration. After that, ions of an n-type impurity are implanted into the SiGe layer 10b to have a predetermined impurity concentration. A SiGe crystal is epitaxially grown while a concentration of Ge contained in the SiGe crystal is gradually increased from an interface between the Si layer 10c and the SiGe crystal to an interface between the SiGe layer 10b and the SiGe crystal in order to alleviate the lattice mismatch, thereby forming the buffer layer 10a. Thereafter, a SiN mask 11 is formed on the SiGe layer 10b (FIG. 2A).

Note that, the method of fabricating the semiconductor device according to this embodiment can be started with the subsequent process by previously preparing a substrate which is obtained by forming the SiN mask 11 on the semiconductor substrate 10 including the Si layer 10c, the buffer layer 10a and the SiGe layer 10b.

(1b) The SiN mask 11 is patterned in predetermined shape by utilizing a photolithography technique, and fins 20 are formed using the SiN mask 11 having the predetermined shape as a mask by utilizing a reactive ion etching (RIE) method (FIG. 2B).

(1c) The SiGe layer 10b and the buffer layer 10a are selectively oxidized to concentrate Ge, thereby forming a SiO₂ oxide film 12 on each of surfaces of the fins 20. Thus, Si contained in each of the SiGe layer 10b and the buffer layer 10a is absorbed into the SiO₂ oxide film 12 to increase a concentration of Ge contained in a portion which is intended to turn into a channel region or the like. The portion which is intended to turn into the channel region or the like is formed as a SiGe channel which has a high Ge concentration, a Ge channel or a strained Ge channel. As a result, the SiO₂ oxide film 12 is thickened, and the SiGe layer 10b is thinned. In addition, the SiO₂ oxide film 12 is also formed on each of bottom portions 20a between the fins 20 (FIG. 2C). Note that, Ge is concentrated in a low-temperature oxidation, which makes it possible to reduce the Ge concentration of the SiGe film 10b from a surface of the SiGe film 10b to an inner central portion thereof. As a result, a lattice constant in the central portion of the SiGe film 10b becomes smaller than that in the surface of the SiGe film 10b.

(1d) The SiN mask 11 is slimmed by using a hot phosphoric acid so as to have nearly the same width as that of the SiGe layer 10b after completion of the oxidation (FIG. 2D).

(1e) The SiO₂ oxide film 12 formed on the surface of the SiGe layer 10b is removed by using a hydrofluoric acid system gas. As a result, the SiGe layer 10b is thinned, so that the fins 20 each having a predetermined thickness are obtained. Likewise, the SiO₂ oxide film 12 formed on each of the bottom portions 20a between the fins 20 is also removed, so that each of the fins 20 is formed so as to have a predetermined height (FIG. 2E).

(1f) In order to perform isolation for the FinFETs, an isolation film 60 made of SiO₂ or the like is deposited over the whole surface and filled in each of the spaces defined between the fins 20 by utilizing the CVD method (FIG. 2F).

(1g) The isolation film 60 is etched back to such a depth that no buffer layer 10a is exposed through the etching processing (FIG. 2G).

(1h) Impurity ions are implanted into each of isolation film upper surfaces 60a between the fins 20. That is to say, when ions of an n-type impurity such as phosphorus (P) are implanted from above into each of the isolation film upper surfaces 60a in a direction indicated by an arrow A, each of the isolation film upper surfaces 60a undergoes the ion implantation although each of the fins 20 does not undergoes the ion implantation because each of the top portions of the fins 20 is coated with the SiN mask 11. Since the impurity ions are implanted into each of the isolation film upper surfaces 60a and also are transversely scattered, each of the lower portions of the fins 20 has a high impurity concentration and thus becomes a punch-through stopper (FIG. 2H).

(1i) A polysilicon layer becoming a gate electrode is deposited over the whole surface. That is to say, after the gate insulating film 31 (made of SiO₂ or the like) is formed by performing thermal oxidation or the like, a polysilicon film 70 is deposited over the whole surface including the surfaces of the fins 20 by utilizing a metal-organic CVD (MOCVD) method or the like (FIG. 2I).

(1j) The polysilicon layer 70 is then flattened with each of upper ends of the SiN mask 11 as a stopper position by utilizing a CMP method (FIG. 2J).

(1k) A second polysilicon layer 71 is deposited on the flattened polysilicon layer 70 and the SiN mask 11 by utilizing the MOCVD method or the like (FIG. 2K).

(1l) A SiN film 12 is deposited so as to have a predetermined thickness by utilizing the MOCVD method, and a photo resist 13 for formation of the gate electrode is then formed on the SiN film 12 (FIG. 2L).

(1m) The SiN film 12 is etched away using the photo resist 13 as a mask by utilizing the RIE method or the like. Thereafter, the photo resist 13 is removed (FIG. 2M).

(1n) The etching is carried out using the SiN film 12 as a mask by utilizing the RIE method using a fluorine system gas such as CF₄. As a result, the gate electrode 30 is formed (FIG. 2N).

(1o) After each exposed portion of the SiN mask 11 and the SiN film 12 are removed, ions of a p-type impurity such as boron (B) are implanted vertically or obliquely into an upper surface of the SiGe layer 10b of each of the fins 20 by using the gate electrode 30 as a mask, thereby forming shallow junction portions (not shown) between the source region and the channel region, and between the drain region and the channel region, respectively. After that, a SiO₂ film 80 is isotropically deposited over the whole surface by utilizing the CVD method or the like for the purpose of forming the sidewall insulating film 34 (FIG. 20).

(1p) The SiO₂ film 80 is etched back to be removed by utilizing the RIE method using a fluorine system gas such as CF₄, thereby forming the sidewall insulating films 34 on the sidewalls of the gate electrode 30 and the SiGe layer 10b, respectively. Here, ions of a p-type impurity such as boron (B) are implanted vertically or obliquely into each of the upper surfaces of the fins 20 by using the gate electrode 30 as a mask and by using each of the sidewall insulating films 34 formed on the side faces of the gate electrode 30, respectively, as a mask edge, thereby forming deep junction portions becoming the source region 40 and the drain region 50, respectively (FIG. 2P).

(1q) After completion of the processes described above, contacts, wirings and the like are formed by using the semiconductor fabricating processes utilizing the known technique, thereby fabricating the p-FinFET.

According to the first embodiment of the present invention, the following effects can be obtained.

1. The relatively large fin height can be ensured as compared with the case where the FinFET is structured after a Ge film having a high Ge concentration is epitaxially grown to have a certain degree of a thickness. Also, the carrier mobility can be improved because the channel region can be formed as the SiGe channel which has the high Ge concentration, the Ge channel, or the strained Ge channel.

2. It is possible to form the FET having the fin structure containing therein the few crystal defects because the SiGe layer is epitaxially grown through the buffer layer in order to form the fins, and no buffer layer having the large dislocation density is used as the channel region. Also, it is possible to suppress the increase in junction leakage current since the ions of the impurity are implanted into the lower portions of the fins to form the punch-through stopper.

3. The Ge concentration of the central portion of the SiGe layer is made smaller than that of the surface of the SiGe layer, which makes it possible to make the lattice constant in the central portion of the SiGe layer smaller than that in the surface of the SiGe layer. As a result, each of the channels formed on the fin surfaces can be given the compressive strains to improve the carrier mobility.

4. No expensive SiGe on insulator (SGOI) substrate or the like is used for isolation, which offers the effect in cost reduction.

A second embodiment of the present invention is such that in the p-FinFET according to the first embodiment, an SGOI substrate is used instead of the Si semiconductor substrate in order to suppress the diffusion of Ge into a bottom portion of a substrate. Fabricating processes will be described in detail hereinafter in consideration of points of difference between the first embodiment and the second embodiment.

FIGS. 3A to 3C are respectively perspective views showing processes for fabricating a p-FinFET according to the second embodiment of the present invention.

(2a) An SGOI substrate is prepared which is formed by laminating a buried oxide (BOX) layer 110d, a Si layer 100c, a buffer layer 100a, and a SiGe layer 100b in order on a Si substrate 100. In addition, a SiN mask 11 is formed on the SiGe layer 100b (FIG. 3A).

A SiGe crystal is epitaxially grown while a concentration of Ge contained in the SiGe crystal is gradually grown from an interface between the Si layer 100c and the SiGe crystal to an interface between the SiGe layer 100b and the SiGe crystal in order to alleviate the lattice mismatch, thereby forming the buffer layer 100a.

The SiGe layer 100b has a nearly uniform Ge concentration corresponding to a Ge concentration of the buffer layer 100a in the interface between the SiGe layer 100b and the buffer layer 100a, and preferably has nearly the same Ge concentration as that of the buffer layer 100a in the interface between the SiGe layer 100b and the buffer layer 100a. In addition, the SiGe layer 100b contains therein an n-type impurity having a predetermined concentration.

(2b) The SiN mask 11 is patterned in predetermined shape by utilizing the photolithography technique, and the RIE is then carried out by using the SiN mask 11 thus patterned to form fins 20 (FIG. 3B).

Processes (2c) and (2d) are the same as those (1c) and (1d) of the first embodiment. FIG. 3C shows a state after completion of the process (2d). Note that, the Ge concentrations of the SiGe layer 100b, the buffer layer 100a and the Si layer 100c may become nearly uniform through the process (2c).

(2e) A SiO₂ oxide film 12 formed on the surface of the SiGe layer 100b is removed by using a hydrofluoric acid system gas. As a result, the SiGe layer 100b is thinned, so that a predetermined fin thickness is obtained. Likewise, the vicinities of the surface of the BOX layer 100d between the fins 20 are also removed in this process. Therefore, this process is preferably carried out while attention is paid to an amount of etched film in accordance with a management for time or the like.

Processes after the process (2e) are the same as those (1i) to (1q) of the first embodiment.

According to the second embodiment of the present invention, the following effects can be obtained in addition to the effects, of the first embodiment, described in the items 1 and 3.

An effect is obtained such that since the SGOI substrate is used, the diffusion of Ge into the bottom portion of the substrate can be suppressed and thus the isolation can be readily carried out. In addition, an effect is offered such that since Ge is concentrated from the transverse direction of the fins, the Ge contained in the SiGe layer is uniformly and highly concentrated with respect to the longitudinal direction of the fins, and thus the thickness of the region having the high Ge concentration can be made not smaller than that of the SiGe layer.

A semiconductor device according to a third embodiment of the present invention has an n-channel FinFET (hereinafter referred to as “an n-FinFET”) in addition to the p-FinFET shown in the first embodiment, and also has at least one p-FinFET and at least one n-FinFET on one piece of semiconductor substrate. The semiconductor device according to the third embodiment of the present invention will be described in detail hereinafter while a method of fabricating the same of the third embodiment will be described in detail.

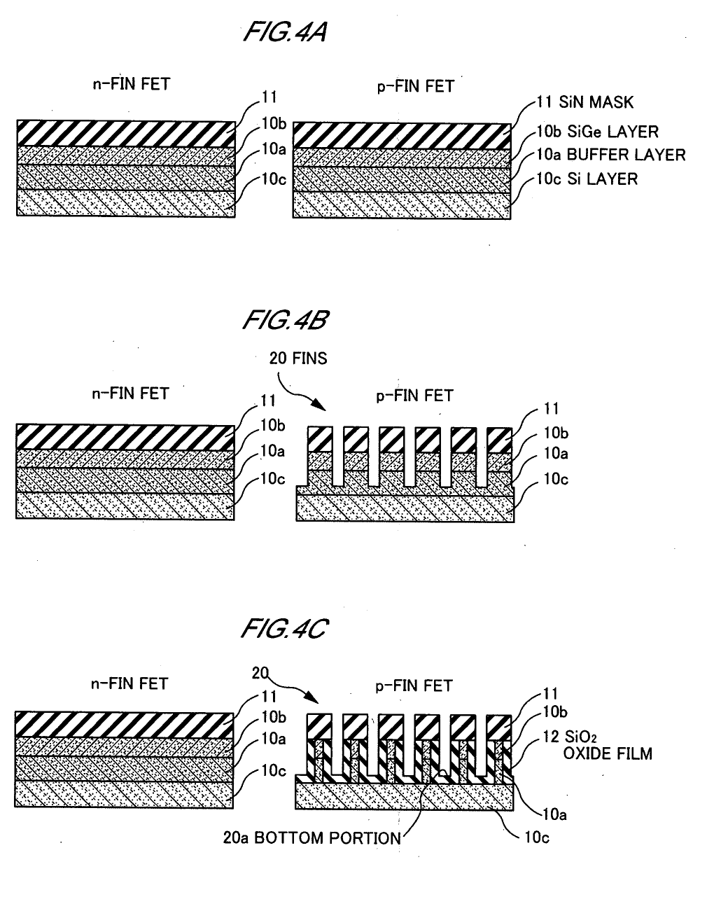

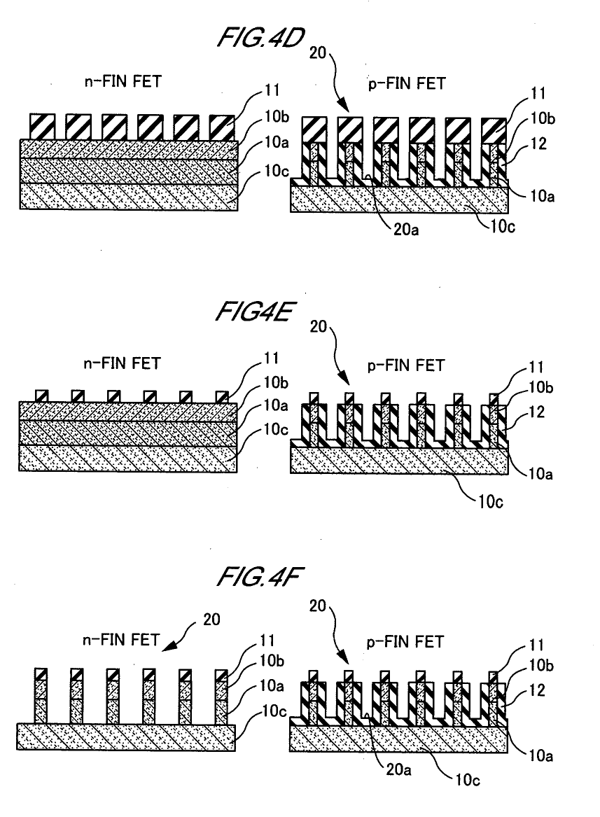

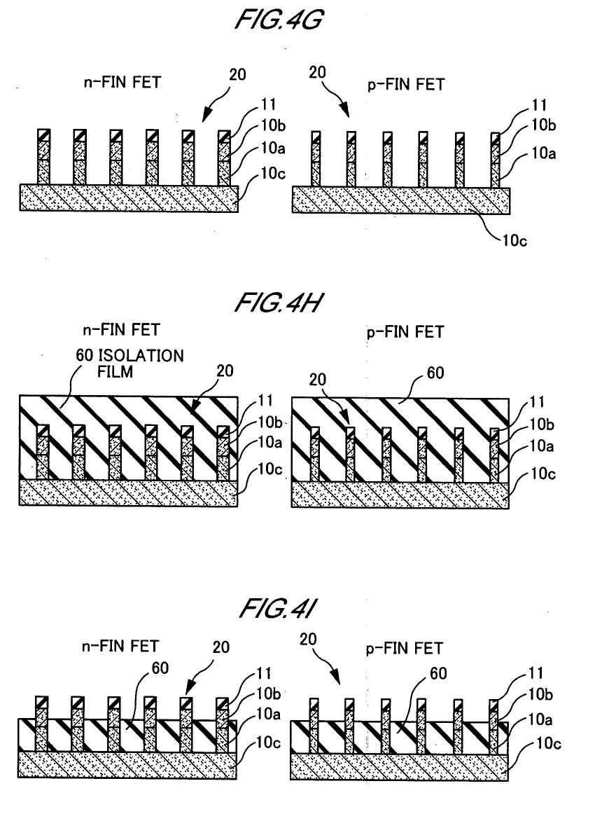

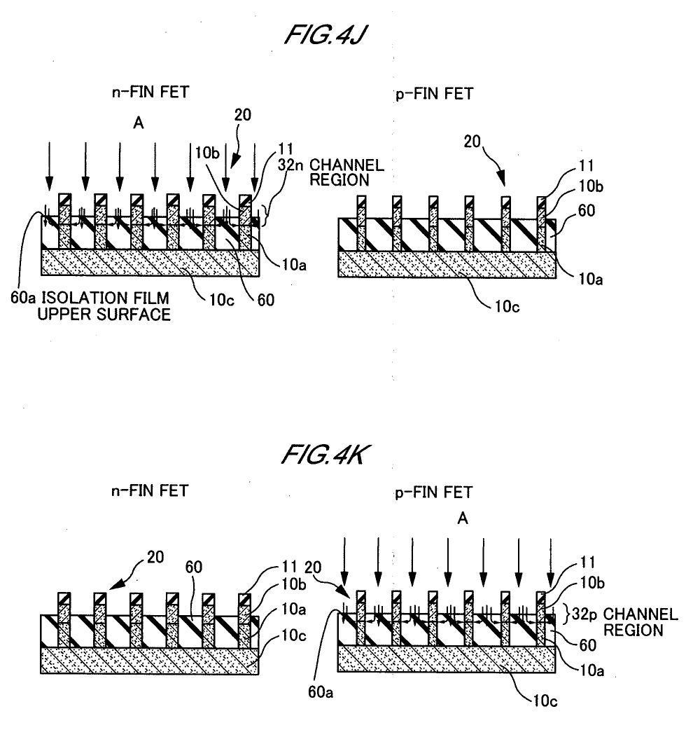

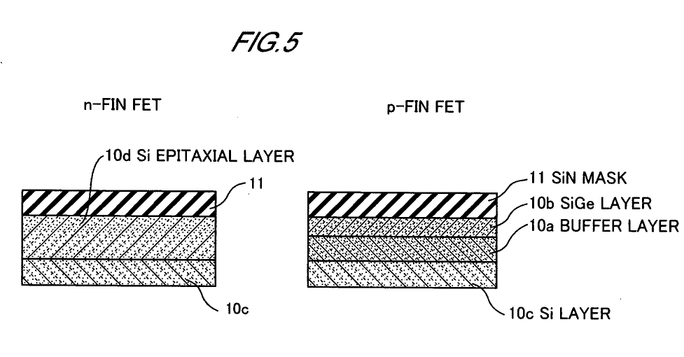

FIGS. 4A to 4K are respectively cross sectional views showing processes for fabricating an n-FinFET and a p-FinFET according to the third embodiment of the present invention. In these figures, processes for fabricating an n-FinFET region in respective stages are shown on a left-hand side, and processes for fabricating a p-FinFET region in respective stages are shown on a right-hand side.

(3a) A buffer layer 10a is formed on a Si layer 10c by utilizing the CVD method, and a SiGe layer 10b is formed on the buffer layer 10a. After that, a SiN mask 11 is formed on the SiGe layer 10b (FIG. 4A).

A SiGe crystal is epitaxially grown while a concentration of Ge contained in the SiGe crystal is gradually increased from an interface between the Si layer 10c and the SiGe crystal to an interface between the SiGe layer 10b and the SiGe crystal in order to alleviate the lattice mismatch, thereby forming the buffer layer 10a.

The SiGe layer 10b has a nearly uniform Ge concentration corresponding to a Ge concentration of the buffer layer 10a in the interface between the SiGe layer 10b and the buffer layer 10a, and preferably has nearly the same Ge concentration as that of the buffer layer 10a in the interface between the SiGe layer 10b and the buffer layer 10a. In addition, the SiGe layer 10b contains therein an n-type impurity having a predetermined concentration in the p-FinFET region, and also contains therein a p-type impurity having a predetermined concentration in the n-FinFET region.

(3b) Firstly, in order to form the p-FinFET region, a photo resist (not shown) is formed on the n-FinFET region, and the processes for fabricating the p-FinFET are selectively made to progress. A SiN mask 11 is patterned in predetermined shape on the p-FinFET region by utilizing the photolithography technique, and fins 20 are then formed using the SiN mask 11 thus patterned as a mask by utilizing the RIE method (FIG. 4B).

(3c) The SiGe layer 10b and the buffer layer 10a are selectively oxidized to concentrate Ge, thereby forming a SiO₂ oxide film 12 on the surface of the SiGe layer 10b and the buffer layer 10a. As a result, Si contained in the SiGe layer 10b and the buffer layer 10a is absorbed into the SiO₂ oxide film 12 to increase the Ge concentration of a portion which is intended to become a channel region or the like. The portion which is intended to become the channel region or the like is formed as a SiGe channel which has a high Ge concentration, a Ge channel or a strained Ge channel. As a result, the SiO₂ oxide film 12 formed on the surface of the SiO₂ oxide film 12 is thickened, and also the SiGe layer 10b is thinned. In addition, the SiO₂ oxide film 12 is also formed on each of bottom portions 20a between the fins 20 (FIG. 4C). Note that, Ge is concentrated by performing the low-temperature oxidation, which makes it possible to decrease the Ge concentration of the SiGe layer 10b from the surface of the SiGe layer 10b to an inner central portion thereof. As a result, a lattice constant in the central portion of the SiGe layer 10b becomes smaller than that in the surface thereof.

(3d) Next, after a photo resist formed on the n-FinFET region is removed, a photo resist (not shown) is formed on the p-FinFET region, and in order to selectively form the fins 20 in the n-FinFET region by utilizing the photolithography technique and the RIE method, the SiN mask 11 is patterned in predetermined shape (FIG. 4D).

(3e) After the photo resist formed on the p-FinFET region is removed, the SiN mask 11 is slimmed in the p-FinFET region and the n-FinFET region by using a hot phosphoric acid so as to have nearly the same width as that of the SiGe layer 10b after completion of the oxidation (FIG. 4E).

(3f) Next, in order to form the n-FinFET region, a photo resist (not shown) is formed on the p-FinFET, and the processes for fabricating the n-FinFET are selectively made to progress. The fins 20 are formed in the n-FinFET region using the SiN mask 11 by utilizing the RIE method (FIG. 4F).

(3g) After the photo resist formed on the p-FinFET region is removed, in the p-FinFET region, the SiO₂ oxide film 12 formed on the surface of the SiN layer 10b and the buffer layer 10a is removed by using a hydrofluoric acid system gas. As a result, the SiGe layer 10b is thinned, so that a predetermined fin thickness is obtained. Likewise, the SiO₂ oxide film 12 formed on each of the bottom portions 20a between the fins 20 is also removed, so that each of the fins 20 is formed to have a predetermined height (FIG. 4G).

(3h) In order to perform isolation for the FinFETs, an isolation film 60 made of SiO₂ or the like is deposited over the whole surface and filled in each of the spaces defined between the fins 20 in the p-FinFET region and the n-FinFET region by utilizing the CVD method, and is then flattened therein (FIG. 4H).

(3i) The isolation film 60 is etched back to such a depth that no buffer layer 10a is exposed through the etching processing (FIG. 4I).

(3j) A photo resist (not shown) is formed on the p-FinFET region, and impurity ions are selectively implanted into each of isolation film upper surfaces 60a between the fins 20 in the n-FinFET region. When the ions of a p-type impurity such as boron (B) or indium (In) are implanted from above into each of the isolation film upper surfaces 60a in a direction indicated by an arrow A, each of the isolation film upper surfaces 60a undergoes the ion implantation although each of the fins 20 does not undergo the ion implantation because each of the top portions of the fins 20 is coated with the SiN mask 11. The impurity ions are implanted into each of the isolation film upper surfaces 60a, and are scattered in the transverse direction as well. Thus, the impurity ions are implanted into each of the lower portions of the fins 20, so that each of portions located below with respect to channel regions 32n in the fins 20 has a high impurity concentration and thus becomes a punch-through stopper (FIG. 4J).

(3k) Next, a photo resist (not shown) is formed on the n-FinFET region, and impurity ions are selectively implanted into each of the isolation film upper surfaces 60a between the fins 20 in the p-FinFET region. When the ions of an n-type impurity such as phosphorus (P) or arsenic (As) are implanted from above into each of the isolation film upper surfaces 60a in a direction indicated by an arrow A, each of the isolation film upper surfaces 60a undergoes the ion implantation although each of the fins 20 does not undergoes the ion implantation because each of the top portions of the fins 20 is coated with the SiN mask 11. The impurity ions are implanted into each of the isolation film upper surfaces 60a, and are scattered in the transverse direction as well. Thus, the impurity ions are implanted into each of the lower portions of the fins 20, so that each of portions located below with respect to channel regions 32p in the fins 20 has a high impurity concentration and thus becomes a punch-through stopper (FIG. 4K).

(3l) Processes after the process (3k) are identical to those (1i) to (1q) shown in the first embodiment, that is, the fabricating processes shown in FIGS. 2I to 2P. After the photo resist is removed, the gate insulating film 31 (made of SiO₂ or the like) is formed by performing the thermal oxidation or the like. After that, the polysilicon layer 70 is deposited on the whole surface including the surfaces of the fins 20 by utilizing the MOCVD method or the like. After completion of the process described above, the polysilicon layer 70 is flattened with each of upper ends of the SiN mask 11 as a stopper position by utilizing the CMP method. The second polysilicon layer 71 is deposited on the polysilicon layer 70 thus flattened and the SiN mask 11 by utilizing the MOCVD method or the like. The SiN film 12 is deposited to have the predetermined thickness by utilizing the MOCVD method, and the photo resist 13 for formation of the gate electrode is then formed on the SiN film 12. After the SiN film 12 is selectively etched away by utilizing the RIE method or the like, the etching is carried out using the resulting SiN film 12 as the mask by utilizing the RIE method using the fluorine system gas such as CF₄. As a result, the gate electrode 30 is formed.

After the exposed portion of the SiN mask 11, and the SiN film 12 are removed, ions of an impurity are implanted vertically or obliquely into the upper surface of the SiGe layer 10b of each of the fins 20 by using the gate electrode 30 as the mask, thereby forming shallow junction portions between the source region and the channel region, and between the drain region and the channel region, respectively.

After that, in order to form the sidewall insulating film 34, the SiO₂ film 80 is isotropically deposited by utilizing the CVD method or the like. The SiO₂ film 80 is then etched back to be removed by utilizing the RIE method using the fluorine system gas such as CF₄, thereby forming the sidewall insulating film 34 on each of the side faces of the gate electrode 30 and the SiGe layer 10b. Also, the ions of the impurity are implanted vertically or obliquely into the upper surface of each of the fins 20 by using the gate electrode 30 as the mask and by using each of the sidewall insulating films 34 formed on the side faces of the gate electrode 30, respectively, as the mask edge, thereby forming the deep junction portions becoming the source region 40 and the drain region 50, respectively.

After completion of the process described above, the contacts, the wirings and the like are formed by using the semiconductor fabricating processes utilizing the known technique, thereby forming the n-FinFET and the p-FinFET.

Note that, in forming the shallow junction portions between the source region and the channel region, and between the drain region and the channel region, respectively, and in forming the deep junction portions becoming the source region and the drain region, respectively, in the case of the n-FinFET, the ions of the n-type impurity such as phosphorus (P) are implanted, while in the case of the p-FinFET, the ions of the p-type impurity such as boron (B) are implanted.

According to the third embodiment of the present invention, the following effects can be obtained.

1. In the p-FinFET, similarly to the corresponding one of the effects of the first embodiment, the effect advantageous in the improvement in the carrier mobility is obtained because the channel region 32p can be formed as the SiGe channel which has the high Ge concentration, the Ge channel or the strained Ge channel. On the other hand, in the n-FinFET, the channel region 32n is formed which has the lower Ge concentration than that of the channel region 32p of the p-FinFET.

2. As described above, the p-FinFET having the SiGe channel having the high Ge concentration, and the n-FinFET having the SiGe channel having the low Ge concentration can be formed on the same substrate. Therefore, the third embodiment of the present invention has especially the effect when the CMOS stricture is obtained.

A fourth embodiment of the present invention is such that in the third embodiment, a Si crystal containing therein no Ge is used as the crystal which is grown on the Si layer in the n-FinFET region.

FIG. 5 is a cross sectional view showing a substrate having a Si layer 10c on which different layers are epitaxially grown in a p-FinFET region and an n-FinFET region, respectively, according to the fourth embodiment of the present invention.

In a region in which the p-FinFET is intended to be formed, a buffer layer 10a is formed on the Si layer 10c by utilizing the CVD method, and a SiGe layer 10b is formed on the buffer layer 10a.

A SiGe crystal is epitaxially grown while a concentration of Ge contained in the SiGe crystal is gradually increased from an interface between the Si layer 10c and the SiGe crystal to an interface between the SiGe layer 10b and the SiGe crystal in order to alleviate the lattice mismatch, thereby forming the buffer layer 10a.

The SiGe layer 10b has a nearly uniform Ge concentration corresponding to a Ge concentration of the buffer layer 10a in the interface between the SiGe layer 10b and the buffer layer 10a, and preferably has nearly the same Ge concentration as that of the buffer layer 10a in the interface between the SiGe layer 10b and the buffer layer 10a. In addition, the SiGe layer 10b contains therein an n-type impurity having a predetermined concentration.

On the other hand, in a region in which the n-FinFET is intended to be formed, a Si crystal is epitaxially grown to form a Si epitaxial layer 10d. The Si epitaxial layer 10d contains therein a p-type impurity having a predetermined concentration.

Thereafter, a SiN mask 11 is formed on each of the p-FinFET region and the n-FinFET region.

A method of fabricating the n-FinFET and the p-FinFET is the same as that according to the third embodiment, and thus its description is omitted here for the sake of simplicity.

According to the fourth embodiment of the present invention, a difference in Ge concentration between the channel region 32p of the p-FinFET and the channel region 32n of the n-FinFET can be made larger than that in the third embodiment. Therefore, the fourth embodiment of the present invention especially has an effect when the CMOS structure is obtained.

A fifth embodiment of the present invention relates to a semiconductor device including a planar type FET in addition to the FinFET described in each of the first to third embodiments. The semiconductor device according to the fifth embodiment of the present invention will be described in detail hereinafter while a method of fabricating the same will be described in detail.

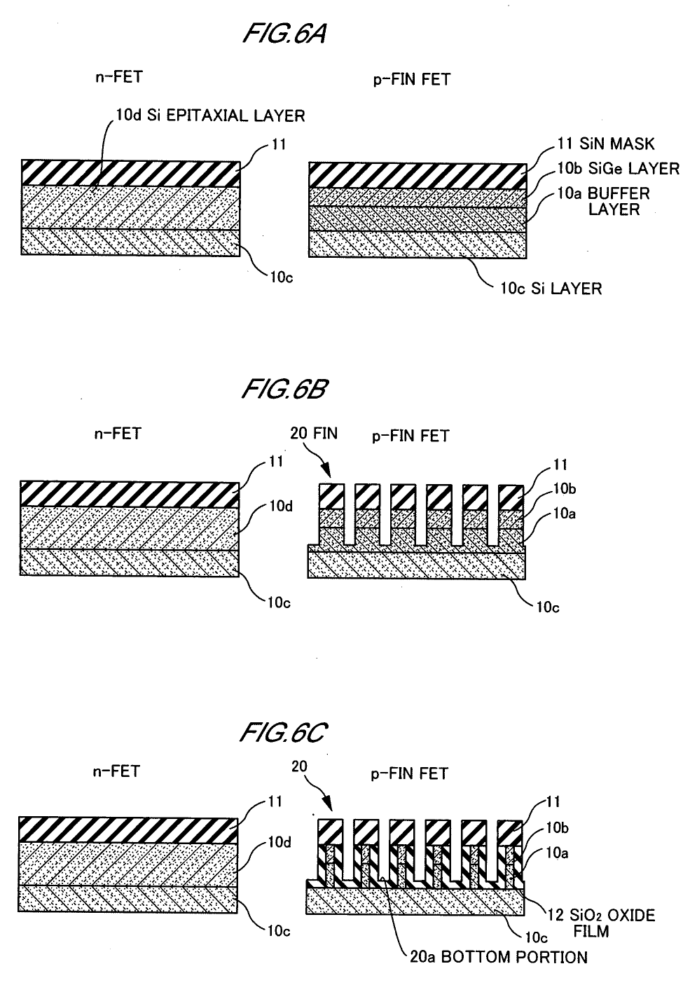

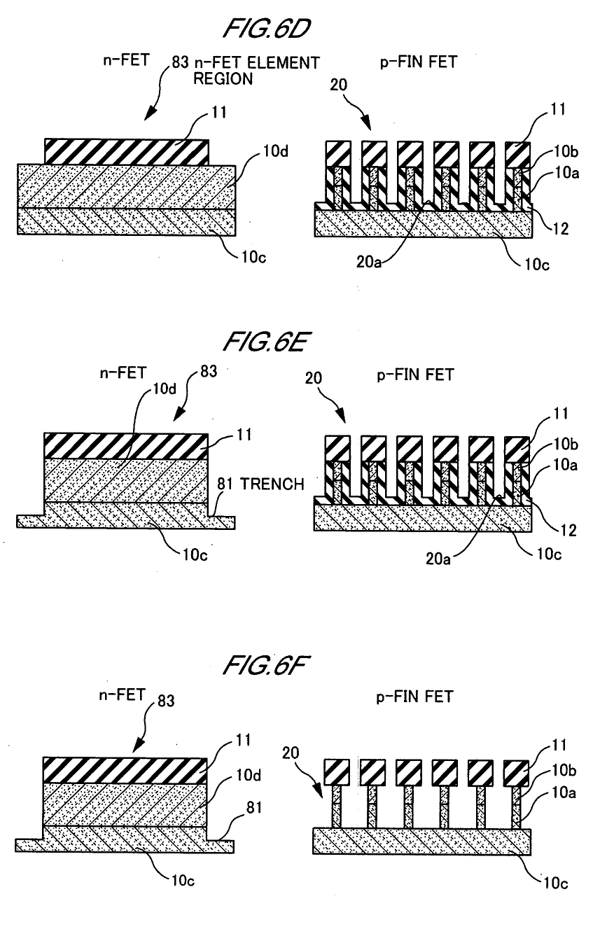

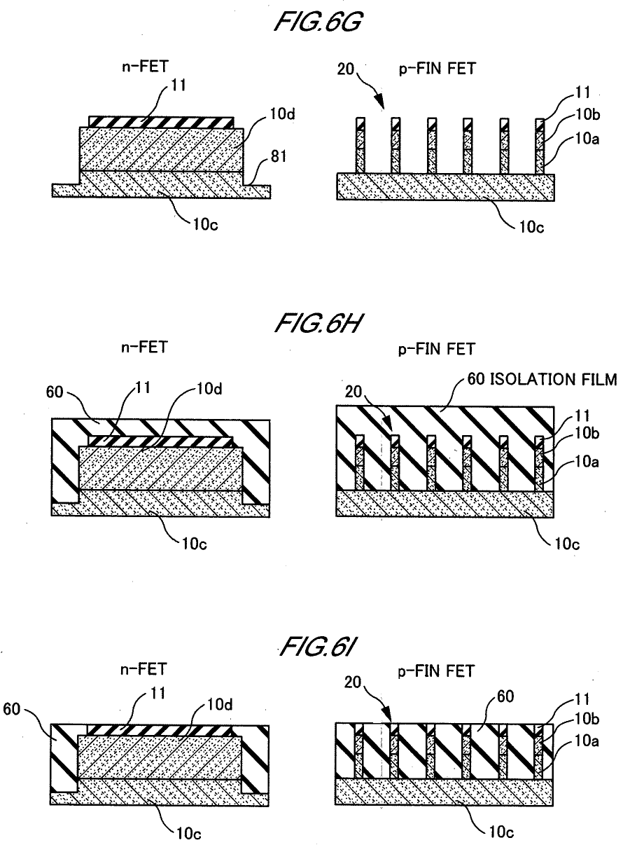

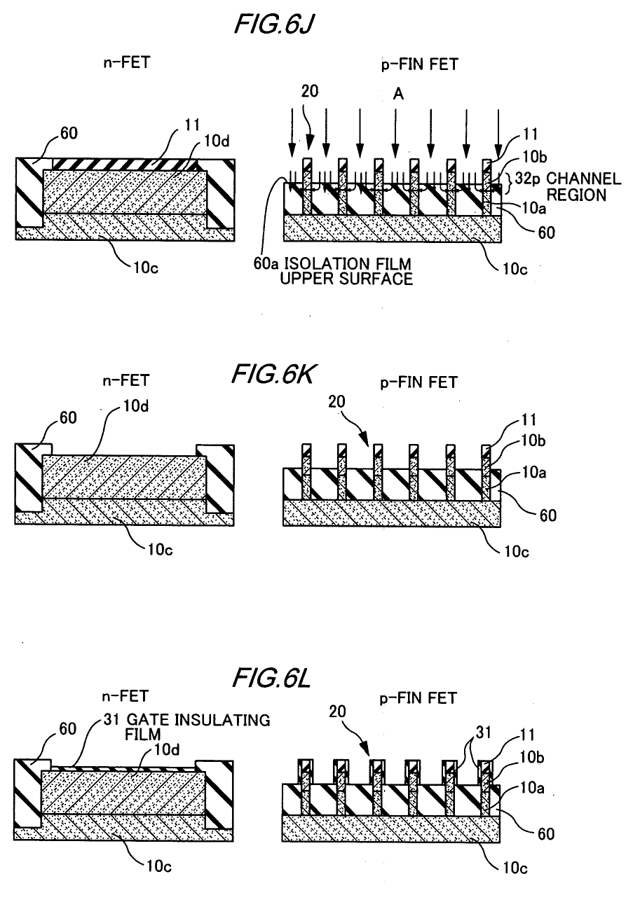

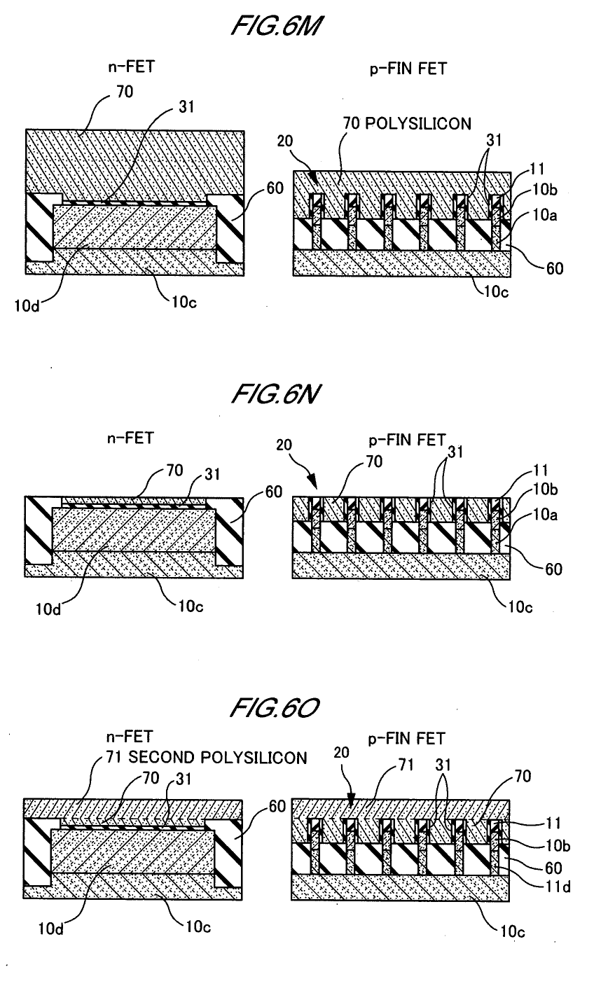

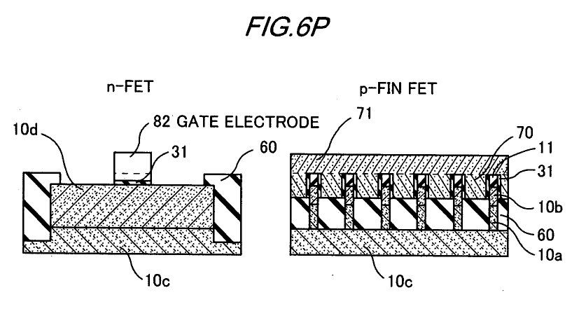

FIGS. 6A to 6P are respectively cross sectional views showing processes for fabricating a FinFET and a planar type FET according to the fifth embodiment of the present invention. A description will now be given with respect to the case where the FinFET is a p-FinFET, and the planar type FET is an n-channel planar type FET (hereinafter referred to as “an n-FET”). In these figures, the processes for fabricating an n-FET region in respective stages are shown on a left-hand side, and the processes for fabricating a p-FinFET region in respective stages are shown on a right-hand side.

(5a) In a region in which the p-FinFET is intended to be formed, a buffer layer 10a is formed on a Si layer 10c by utilizing the CVD method, and a SiGe layer 10b is formed on the buffer layer 10a.

A SiGe crystal is epitaxially grown while a concentration of Ge contained in the SiGe crystal is gradually increased from an interface between the Si layer 10c and the SiGe crystal to an interface between the SiGe layer 10b and the SiGe crystal in order to alleviate the lattice mismatch, thereby forming the buffer layer 10a.

The SiGe layer 10b has a nearly uniform Ge concentration corresponding to a Ge concentration of the buffer layer 10a in the interface between the SiGe layer 10b and the buffer layer 10a, and preferably has nearly the same Ge concentration as that of the buffer layer 10a in the interface between the SiGe layer 10b and the buffer layer 10a. In addition, the SiGe layer 10b contains therein an n-type impurity having a predetermined concentration.

On the other hand, in a region in which the n-FET is intended to be formed, a Si crystal is epitaxially grown on the Si semiconductor layer 10c to form a Si epitaxial layer 10d. The resulting Si epitaxial layer 10d contains therein a p-type impurity having a predetermined concentration.

Thereafter, a SiN mask 11 is formed on each of the p-FinFET region and the n-FET region (FIG. 6A).

(5b) Firstly, in order to form the p-FinFET region, a photo resist (not shown) is formed on the n-FET region, and the processes for fabricating the p-FinFET are selectively made to progress. That is to say, the SiN mask 11 is patterned in predetermined shape in the p-FinFET region by utilizing the photolithography technique, and fins 20 are then formed using the SiN mask 11 thus patterned by utilizing the RIE method (FIG. 6B).

(5c) The SiGe layer 10b and the buffer layer 10a are selectively oxidized to concentrate Ge, thereby forming a SiO₂ oxide film 12 on the surface of the SiGe layer 10b and the buffer layer 10a. As a result, Si contained in each of the SiGe layer 10b and the buffer layer 10a is absorbed into the SiO₂ oxide film 12 to increase a Ge concentration in a portion which is intended to become a channel region or the like. The portion which is intended to become the channel region or the like is formed as a SiGe channel, a Ge channel or a strained Ge channel which has a high concentration. As a result, the SiO₂ oxide film 12 formed on the surface of the SiO₂ oxide film 12 is thickened, and the SiGe layer 10b is thinned. In addition, the SiO₂ oxide film 12 is also formed on each of bottom portions 20a between the fins 20 (FIG. 6C). Note that, Ge is concentrated by performing the low-temperature oxidation, which makes it possible to decrease the Ge concentration of the SiGe layer 10b from the surface of the SiGe layer 10b to an inner central portion thereof. As a result, a lattice constant in the central portion of the SiGe layer 10b becomes smaller than that in each of the surface.

(5d) Next, after a photo resist (not shown) formed on the n-FET region is removed, a photo resist (not shown) is formed on the p-FinFET region, and in order to selectively form an n-FET element region 83 in the n-FET region by utilizing the photolithography technique and the RIE method, the SiN mask 11 is patterned in predetermined shape (FIG. 6D).

(5e) The etching is carried out by using the resulting SiN mask 11 until the Si semiconductor layer 10c is reached, thereby forming a trench 81 for isolation for the n-FET element region 83 (FIG. 6E).

(5f) After the photo resist (not shown) formed on the p-FinFET region is removed, in the p-FinFET region, the SiO₂ oxide film 12 formed on the surface of the SiGe layer 10b and the buffer layer 10a is removed by using a hydrofluoric acid system gas. As a result, the SiGe layer 10b is thinned, so that a predetermined fin thickness is obtained. Likewise, the SiO₂ oxide film 12 formed on each of bottom portions 20a between the fins 20 is also removed, so that each of the fins 20 is formed to have a predetermined height (FIG. 6F).

(5g) In each of the p-FinFET region and the n-FET region, the SiN mask 11 is slimmed by using a hot phosphoric acid. In the p-FinFET region, a width of the SiN mask 11 after completion of the slimming becomes nearly the same as that of the SiGe layer 10b after the SiO₂ oxide film 12 is removed (FIG. 6G).

(5h) In order to perform isolation for the elements in each of the p-FinFET region and the n-FET region, an isolation film 60 made of SiO₂ or the like is deposited over the whole surface and filled in each of the spaces defined between the fins 20, and the trench 81 by utilizing the CVD method (FIG. 6H).

(5i) The isolation film 60 is flattened by using the SiN mask 11 as a stopper so that a height of the isolation film 60 in the p-FinFET region becomes equal to that of the isolation film 60 in the n-FET region (FIG. 6I).

(5j) Next, a photo resist (not shown) is formed on the n-FET region, and the isolation film 60 in the p-FinFET region is selectively etched back to such a depth that no buffer layer 10a is exposed through the etching processing. Next, impurity ions are implanted into each of isolation film upper surfaces 60a between the fins 20 in the p-FinFET region. When the ions of an n-type impurity such as phosphorus (P) or arsenic (As) are implanted from above into each of the isolation film upper surfaces 60a in a direction indicated by an arrow A, each of the isolation film upper surfaces 60a undergoes the ion implantation although each of the fins 20 does not undergo the ion implantation because each of the top portions of the fins 20 is coated with the SiN mask 11. The impurity ions are implanted into each of the isolation film upper surfaces 60a, and also are transversely scattered. Thus, the impurity ions are implanted into each of the lower portions as well of the fins 20. As a result, each of the portions located below with respect to the channel regions 32p if the fins 20 has a high impurity concentration, and thus becomes a punch-through stopper (FIG. 6J).

(5k) After the photo resist formed on the n-FET region is removed, a photo resist (not shown) is formed on the p-FinFET region, and the SiN mask 11 formed in the n-FET region is removed (FIG. 6K).

(5l) After the photo resist (not shown) formed on the p-FinFET region is removed, a gate insulating film (made of SiO₂ or the like) 31 is formed in each of the p-FinFET region and the n-FET region by performing thermal oxidation or the like (FIG. 6L).

(5m) A polysilicon film 70 becoming a gate electrode is deposited. That is to say, a polysilicon film 70 is deposited over the p-FinFET region and the n-FET region by utilizing the MOCVD method or the like (FIG. 6M).

(5n) After completion of the process described above, the polysilicon layer 70 is flattened with each of upper ends of the SiN mask 11 in the p-FinFET region as a stopper position by utilizing the CMP method (FIG. 6N).

(5o) A second polysilicon layer 71 is deposited on the polysilicon layer 70 thus flattened and the SiN mask 11 by utilizing the MOCVD method or the like (FIG. 60).

(5p) A photo resist (not shown) is formed on the p-FinFET region, and a gate electrode 82 is then selectively formed so as to have a predetermined pattern in the n-FET region (FIG. 6P).

(5q) The processes for the p-FinFET region after the process (5p) are identical to those (1l) to (1q) shown in the first embodiment, that is, the fabricating processes shown in FIGS. 2L to 2P, respectively. That is to say, after the photo resist formed on the p-FinFET region is removed, the photo resist (not shown) is formed on the n-FET region, the SiN film 12 is deposited to have the predetermined thickness by utilizing the MOCVD method, and the photo resist 13 for formation of the gate electrode is then formed on the SiN film 12. After the SiN film 12 is selectively etched away by utilizing the RIE method or the like, the etching is carried out using the resulting SiN film 12 as the mask by utilizing the RIE method using the fluorine system gas such as CF₄. As a result, the gate electrode 30 is formed. After the SiN mask 11 and the SiN film 12 are removed, ions of the p-type impurity such as boron (B) are implanted vertically or obliquely into each of the upper surfaces of the fins 20 using the gate electrode 30 as the mask, thereby forming the shallow junction portions between the source region 40 and the channel region, and between the drain region 50 and the channel region, respectively. After that, in order to form the sidewall insulating film 34, the SiO₂ film 80 is isotropically deposited over the whole surface by utilizing the CVD method or the like. The SiO₂ film 80 is then etched back by utilizing the RIE method using the fluorine system gas such as CF₄, thereby forming the sidewall insulating films 34 on each of the side faces of the gate electrode 30 and the SiGe layer 10b. Here, the ions of the p-type impurity such as boron (B) are implanted vertically or obliquely into each of the upper surfaces of the fins 20 by using the gate electrode 30 as the mask and by using the sidewall insulating film 34 formed on each of the side faces of the gate electrode 30 as the mask edge, thereby forming the deep junction portions becoming the source region 40 and the drain region 50, respectively.

(5r) On the other hand, in the n-FET region, the ions of the n-type impurity such as phosphorus (P) are implanted into the upper surface, thereby forming the shallow junction portions between the source region and the channel region, and between the drain region and the channel region, respectively. Next, in order to form the gate sidewall, the SiO₂ film is isotropically deposited over the whole surface by utilizing the CVD method or the like. The SiO₂ film is then etched back to be removed by utilizing the RIE method using the fluorine system gas such as CF₄, thereby forming the gate sidewall. The ions of the n-type impurity such as phosphorus (P) are implanted into the upper surface, thereby forming the deep junction portions becoming the source region and the drain region, respectively.

After completion of the processes described above, the contacts, the wirings and the like are formed by using the semiconductor fabricating processes utilizing the known technique, thereby fabricating the p-FinFET and the n-FET.

According to the fifth embodiment of the present invention, in addition to the effects shown in the first to fourth embodiments, it is possible to obtain the semiconductor device in which the FinFET and the planar type FET are formed on the same substrate and are embedded.

Although the FinFET contributes to the high integration, and allows the large current promotion to be realized, the planar type FET may be required to structure the peripheral circuits. Therefore, the fifth embodiment of the present invention has an advantageous effect when the actual integrated semiconductor device is structured.

It should be noted that each of the above-mentioned first to fifth embodiments is merely an embodiment, the present invention is not intended to be limited thereto, and the various changes thereof can be made without departing from the gist of the invention. In addition, the constituent elements of each of the above-mentioned first to fifth embodiments can be arbitrarily combined with one another.

What is claimed is:

1. A semiconductor device, comprising:
a fin including a buffer layer made of SiGe and formed on a Si layer, and a SiGe layer formed on the buffer layer, the SiGe layer having a Ge concentration corresponding to a Ge concentration of the buffer layer in an interface between the buffer layer and the SiGe layer;
a gate electrode formed on a side face of the fin through a gate insulating film;
a channel region formed in a region within the fin facing the gate electrode through the gate insulating film, the channel region being selectively provided within the SiGe layer of the buffer layer and the SiGe layer included in the fin; and
a source region and a drain region formed within the fin, the channel region being formed between the source region and the drain region.

2. A semiconductor device according to claim 1, further comprising an isolation layer for isolating a semiconductor element region comprising the fin, the channel region, and the source region and the drain region formed therein from any of other semiconductor element regions, a surface of the isolation layer being located in a position higher than that of the interface between the buffer layer and the SiGe layer.

3. A semiconductor device according to claim 1, wherein the Ge concentration of the buffer layer increases substantially along a height direction.

4. A semiconductor device according to claim 1, wherein the SiGe layer has the Ge concentration substantially equal to the Ge concentration of the buffer layer in the interface between the SiGe layer and the buffer layer.

5. A semiconductor device according to claim 1, wherein the Ge concentration in an inner central portion of the SiGe layer is smaller than that in a surface of the SiGe layer.

6. A semiconductor device according to claim 1, wherein the fin has a high impurity concentration in its portion located below with respect to the channel region.

7. A semiconductor device according to claim 1, further comprising a transistor including a fin made of a Si crystal containing therein no Ge, the transistor being formed on the Si layer.

8. A semiconductor device according to claim 1, further comprising a transistor having a planar structure, the transistor being formed on the Si layer.

9. A semiconductor device, comprising:
a p-channel transistor having a first fin including a first buffer layer made of SiGe and formed on a Si layer, and a first SiGe layer formed on the first buffer layer, the first SiGe layer having a Ge concentration corresponding to a Ge concentration of the first buffer layer in an interface between the first buffer layer and the first SiGe layer, a first gate electrode formed on a side face of the first fin through a first gate insulating film, a first channel region formed in a region within the first fin facing the first gate electrode through the first gate insulating film, the first channel region being selectively provided within the first SiGe layer of the first buffer layer and the first SiGe layer included in the first fin, and a first source region and a first drain region formed within the first fin, the first channel region being formed between the first source region and the first drain region; and
an n-channel transistor having a second fin formed on the Si layer, a second gate electrode formed on a side face of the second fin through a second gate insulating film, a second channel region formed in a region within the second fin facing the second gate electrode through the second gate insulating film, the second channel region having a Ge concentration smaller than that of the first channel region, and a second source region and a second drain region formed within the second fin, the second channel region being formed between the second source region and the second drain region.

10. A semiconductor device according to claim 9, further comprising an isolation layer for isolating the p-channel transistor and the n-channel transistor from each other, a surface of the isolation layer being located in a position higher than that of the interface between the first buffer layer and the first SiGe layer.

11. A semiconductor device according to claim 9, wherein the Ge concentration of the first buffer layer increases substantially along a height direction.

12. A semiconductor device according to claim 9, wherein the second fin is made of a Si crystal containing therein no Ge.

13. A semiconductor device according to claim 9, wherein the second fin comprises a second buffer layer made of SiGe and formed on the Si layer, and a second SiGe layer formed on the second buffer layer, the second SiGe layer having a Ge concentration corresponding to a Ge concentration of the second buffer layer in an interface between the second buffer layer and the second SiGe layer.

14. A semiconductor device according to claim 13, wherein the first SiGe layer has the Ge concentration substantially equal to that of the first buffer layer in the interface between the first SiGe layer and the first buffer layer, and the second SiGe layer has the Ge concentration substantially equal to that of the second buffer layer in the interface between the second SiGe layer and the second buffer layer.

15. A semiconductor device according to claim 13, wherein the Ge concentration in an inner central portion of the first SiGe layer is smaller than that in a surface of the first SiGe layer.

16. A semiconductor device according to claim 15, wherein the second SiGe layer has an approximately uniform Ge concentration.

17. A method of fabricating a semiconductor device, comprising:
patterning a substrate formed by laminating a Si layer, a buffer layer made of SiGe, and a SiGe layer having a Ge concentration corresponding to a Ge concentration of the buffer layer in an interface between the buffer layer and the SiGe layer in predetermined shape to form a fin;
oxidizing surfaces of the buffer layer and the SiGe layer of the fin to form an oxide layer in order to increase the Ge concentration of the fin;
removing the oxide layer by performing etching;
forming a gate insulating film on a side face of the fin from which the oxide layer is removed by performing the etching;
forming a gate electrode on the side face of the fin through the gate insulating film; and
implanting ions into the fin by using the gate electrode as a mask to form a source region and a drain region.

18. A method of fabricating a semiconductor device according to claim 17, wherein the buffer layer is formed by utilizing an epitaxial method so that its Ge Concentration increase substantially in a height direction.

19. A method of fabricating a semiconductor device according to claim 17, wherein the SiGe layer is formed so as to have the Ge concentration substantially equal to that of the buffer layer in the interface between the SiGe layer and the buffer layer.

20. A method of fabricating a semiconductor device according to claim 17, wherein when the Ge concentration of the fin is increased, the oxide layer is formed by performing low-temperature oxidation so that the Ge concentration in an inner central portion of the fin becomes smaller than that in a surface of the fin.
